(19) United States
(12) Patent Application Publication
(10) Pub. No.: US 2013/0325408 A1
(43) Pub. Date: Dec. 5, 2013

(54) TWO DIMENSIONAL NMR OF DIFFUSION AND RELAXATION FOR MATERIAL CHARACTERIZATION

(71) Applicant: Yi-Qiao Song, Newton, MA (US)

(72) Inventor: Yi-Qiao Song, Newton, MA (US)

(73) Assignee: SCHLUMBERGER TECHNOLOGY CORPORATION, Sugarland, TX (US)

(21) Appl. No.: 13/980,551

(22) PCT Filed: Jan. 27, 2012
(86) PCT No.: PCT/US2012/022822

§ 371 Date: Aug. 21, 2013

Related U.S. Application Data
(60) Provisional application No. 61/437,122, filed on Jan. 28, 2011.

(51) Int. Cl. G01R 33/54

(52) U.S. Cl. CPC G01R 33/54
USPC 702/189

(57) ABSTRACT

Processing nuclear magnetic resonance data to obtain information regarding material properties is described. This processing can include, for example, compression techniques that can be implemented to lower the required operating memory. In some embodiments, a compression technique can be chosen based on the available operating memory of the computer system. By doing so, an efficient compression algorithm can be selected. In some embodiments, a Lanczos bidiagonalization algorithm, for example, an IRLBA algorithm, can be used for data compression.

### BACKGROUND

For many years, nuclear magnetic resonance (“NMR”) has been an important tool in geological formation evaluation. General background of NMR well logging can be found, for example, in U.S. Pat. No. 5,023,551 to Kleinberg et al., which is assigned to the same assignee as the present invention and herein incorporated by reference in its entirety.

The nuclei of many chemical elements may comprise angular momentum (“spin”) and a magnetic moment, which may be considered as a moment of electrons and nuclear particles caused by the intrinsic spin of a particle and the orbital motion of a particle, as around a nucleus. In an externally applied static magnetic field, the spins of nuclei align themselves along the direction of the static field. This equilibrium situation can be disturbed by a pulse of an oscillating magnetic field (e.g., a RF pulse) that tips the spins away from the static field direction. The angle through which the spins are tipped is given by θ=γB₁ tₚ/2, where γ is the gyromagnetic ratio, B₁ is the linearly polarized oscillating field strength, and tₚ is the duration of the pulse. Tipping pulses of ninety and one hundred eighty degrees are most common.

After tipping, two things occur simultaneously. First, the spins precess around the direction of the static field at the Larmor frequency, given by ω=γB₀, where B₀ is the strength of the static field and γ is the gyromagnetic ratio (for hydrogen nuclei, γ/2π=4258 Hz/Gauss, so, for example, in a static field of 235 Gauss, the hydrogen spins would precess at a frequency of 1 MHz). Second, the spins return to the equilibrium direction according to a decay time, T₁, which is known as the spin-lattice relaxation time. Because this spin-lattice relaxation occurs along the equilibrium direction, T₁ is also referred to as the longitudinal relaxation time constant.

Also associated with the spin of molecular nuclei is a second relaxation time, T₂, called the spin-spin relaxation time. At the end of a ninety-degree tipping pulse, all the spins are pointed in a common direction perpendicular, or transverse, to the static field, and the spins all precess at the Larmor frequency. However, because of small fluctuations in the static field induced by other spins or paramagnetic impurities, the spins precess at slightly different frequencies, and the transverse magnetization dephases with a time constant T₂, which is also referred to as the transverse relaxation time constant.

A standard technique for measuring T₂, both in the laboratory and in well logging, uses a RF pulse sequence known as the CPMG (Carr-Purcell-Meiboom-Gill) sequence. After a wait time that precedes each pulse sequence, a ninety-degree pulse tips the spins into the transverse plane and causes the spins to start precessing. Then, a one hundred eighty-degree pulse is applied that keeps the spins in the measurement plane, but causes the spins, which are dephasing in the transverse plane, to reverse direction and to refocus. By repeatedly reversing the spins using a series of one hundred and eighty degree pulses, a series of “spin echoes” are produced. The train of echoes may be measured and processed to determine the irreversible de-phasing time constant, T₂. In well logging applications, the detected spin echoes have been used to extract oilfield parameters such as porosity, pore size distribution, and oil viscosity.

In theory, other laboratory NMR measurements may be applied in well-logging to extract additional information about the oilfield, but in practice, the nature of well-logging and the borehole environment make implementing some laboratory NMR measurements difficult. For example, inversion recovery is a common laboratory technique for measuring T₁. In an inversion recovery measurement, a one-hundred eighty degree pulse is applied to a system of spins aligned along the static magnetic field in order to reverse the direction of the spins. The system of spins thus perturbed begins to decay toward their equilibrium direction according to T₁. To measure the net magnetization, a ninety-degree pulse is applied to rotate the spins into the transverse plane and so induce a measurable signal. The signal will begin to decay as the spins dephase in the transverse plane, but the initial amplitude of the signal depends on the “recovery time” between the one-hundred eighty degree pulse and the ninety-degree pulse. By repeating this experiment for different recovery times and plotting the initial amplitude of the signal against recovery time, T₁ may be determined. While this technique has been successfully used in the laboratory for several years, inversion recovery is very time consuming, and those of ordinary skill in the art recognize that inversion recovery may be unsuitable for well logging applications.

### BRIEF SUMMARY

Some embodiments of the invention provide for systems and methods for processing nuclear magnetic resonance data. More particularly, but not by way of limitation, processing nuclear magnetic resonance data to obtain information regarding material properties is described. By processing the nuclear magnetic resonance data obtained from a material—such as a rock, a rock core, a food stuff, a fluid, a fluid flow, a chemical solution, a chemical compound, a solid material and/or the like—determinations can be made about properties of the material, such as for example its structure, its composition and/or the like. In nuclear magnetic resonance techniques, spin behavior of the nuclei in a material being analyzed may be processed to determine a structure of the material, the composition of the material and/or the like.

This processing can include, for example, compression techniques that lower the required operating memory. In some embodiments, a compression technique can be chosen based on the available operating memory of the computer system. By doing so, an efficient compression algorithm can be selected. In some embodiments, a Lanczos bidiagonalization algorithm, an augmented Implicitly Restarted Lanczos Bidiagonalization method (IRLBA) algorithm or a window sum algorithm can be used. In some embodiments, the processing can be configured to analyze the compressed nuclear magnetic resonance data to extract information about the system of nuclear spins. In some embodiments, the processing can transform the nuclear magnetic resonance data into a vector prior to compressing the nuclear magnetic resonance data.

In some embodiments, a method of extracting information about a system of nuclear spins is provided that performs a plurality of nuclear magnetic resonance measurements on the system of nuclear spins and acquires nuclear magnetic resonance data from the plurality of nuclear magnetic resonance measurements. Then the nuclear magnetic resonance data can be expressed using a kernel. A compression algorithm can be selected that does not require substantially more memory than the available computer RAM and then the nuclear magnetic resonance data is compressed using the selected compression algorithm. The compressed nuclear magnetic resonance data can then be analyzed to extract information about the system of nuclear spins. In some embodiments, the compression algorithm selected to compress the data can be a Lanczos bidiagonalization algorithm, an IRLBA algorithm or a window sum algorithm. In some embodiments, the nuclear magnetic resonance data is compressed along each dimension of the kernel.

In some embodiments, the available computer RAM can be determined prior to selecting the compression algorithm. In some embodiments, the selecting a compression algorithm that does not require substantially more memory than the available computer RAM includes selecting the compression algorithm from a listing of compression algorithms that require a variety of memory for processing. For example, the listing of compression algorithms can include Jdsvd, Irlanb, Matlab SVDs, and Irlbsvd algorithms.

In some embodiments, a method of extracting information about a system of nuclear spins is provided. The method can perform a plurality of nuclear magnetic resonance measurements on the system of nuclear spins and acquire nuclear magnetic resonance data from each of the plurality of nuclear magnetic resonance measurements. The nuclear magnetic resonance data can be expressed using a kernel, the nuclear magnetic resonance data (or kernel that expressed the data) can be compressed using a Lanczos bidiagonalization algorithm, and the compressed nuclear magnetic resonance data can be analyzed to extract information about the system of nuclear spins. In some embodiments, the Lanczos bidiagonalization algorithm can be an IRLBA algorithm.

In some embodiments, a method of extracting information about a measurement system is provided. Data can be acquired about the measurement system and the data can be expressed as a kernel resulting in kernel data. This kernel data can then be compressed using a Lanczos bidiagonalization algorithm and then analyzed to extract information about the measurement system.

In some embodiments, a method of extracting information about a measurement system is provided. Data can be acquired about the measurement system and the data can be expressed as a kernel resulting in kernel data. The available operating memory can be determined for the system executing the method. This kernel data can then be compressed using a compression algorithm that does not require substantially more memory than the available operating memory and then analyzed to extract information about the measurement system. For example, the compression algorithm can be an IRLBA algorithm, a window sum algorithm, and/or any Lanczos bidiagonalization algorithm.

### BRIEF DESCRIPTION OF THE DRAWINGS

FIG. 1 is a sequence of magnetic field pulses, such as RF pulses, that may be applied to a system of nuclear spins, such as in a fluid in a rock, in accordance with some embodiments of the invention.

FIG. 2 is a magnetic field pulse sequence that includes an inversion recovery sequence followed by a CPMG sequence according to some embodiments of the invention.

FIG. 3 is a driven equilibrium-refocusing sequence according to some embodiments of the invention.

FIG. 4 is a flowchart of a process for performing a Laplace inversion using an augmented Implicitly Restarted Lanczos Bidiagonalization method (IRLBA) compression algorithm.

FIG. 5 is a flowchart of a process for performing a Laplace inversion using any of a number of compression algorithms according to some embodiments of the invention.

FIG. 6 is a flowchart of a process for computing an augmented Lanczos bidiagonalization of a data set according to some embodiments of the invention.

FIG. 7 is a flowchart of a process for computing a partial Lanczos bidiagonalization according to some embodiments of the invention.

FIG. 8 is a simplified block diagram of a computational system that can be used to implement the various embodiments of the invention.

### DETAILED DESCRIPTION

The ensuing description provides some embodiment(s) of the invention, and is not intended to limit the scope, applicability or configuration of the invention or inventions. Various changes may be made in the function and arrangement of elements without departing from the scope of the invention as set forth herein. Some embodiments maybe practiced without all the specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

Some embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process is terminated when its operations are completed, but could have additional steps not included in the figure and may start or end at any step or block. A process may correspond to a method, a function, a procedure, a subroutine, a subprogram, etc. When a process corresponds to a function, its termination corresponds to a return of the function to the calling function or the main function.

Moreover, as disclosed herein, the term “storage medium” may represent one or more devices for storing data, including read only memory (ROM), random access memory (RAM), magnetic RAM, core memory, magnetic disk storage mediums, optical storage mediums, flash memory devices and/or other machine readable mediums for storing information. The term “computer-readable medium” includes, but is not limited to portable or fixed storage devices, optical storage devices, wireless channels and various other mediums capable of storing, containing or carrying instruction(s) and/or data.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium such as storage medium. A processor(s) may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

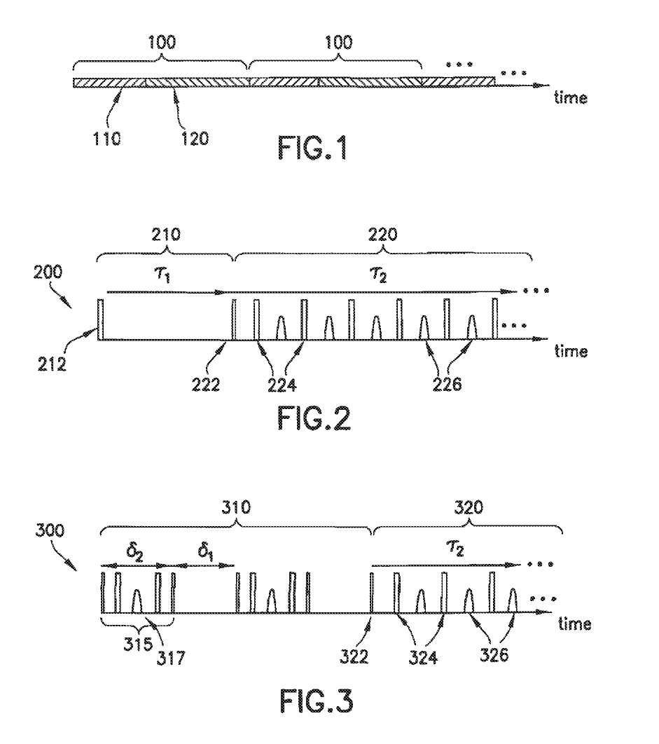

NMR logging typically measures relaxation and diffusion phenomena. FIG. 1 schematically represents a sequence of magnetic field pulses, such as RF pulses, that may be applied to a system of nuclear spins, such as in a fluid in a rock, in accordance with some embodiments of the invention. The magnetic field pulse sequence 100 includes two parts. A first part 110 prepares a system of nuclear spins in a first state. A second part 120 generates from the system of spins a series of magnetic resonance signals. As shown in FIG. 1, the magnetic field pulse sequence 100 may be repeatedly applied, and the magnetic resonance signals detected and combined to build up signal-to-noise ratio.

In generating the series of magnetic resonance signals, the first and second parts preferably excite spins at about the same frequency range. For example, a standard CPMG sequence with a series of 180-degree pulses tends to refocus on-resonance spins, namely those spins having a frequency substantially equal to the Larmor frequency, and the observed CPMG signal primarily includes such on-resonance spins. Accordingly, a standard CPMG sequence would be preferably paired with a first part that also primarily excites on-resonance spins. For a first part that affects primarily off resonance spins, such as a constant RF irradiation (discussed below), the second part preferably is designed to excite substantially the same off-resonance spins. A CPMG-like sequence, in which composite pulses designed to refocus the off-resonance spins replace the 180-degree pulses, may be used in such magnetic pulse sequences. Those of skill in the art will be able to design other types of refocusing sequences to refocus spins having different off-resonance frequencies.

For example, FIG. 2 shows a magnetic field pulse sequence 200 that includes an inversion recovery sequence 210 followed by a CPMG sequence 220. The inversion recovery sequence includes a 180-degree pulse 212 that reverses the direction of the system of spins, followed by a recovery time, τ₁. After the recovery time, which is typically less than T₁, the CPMG sequence 220 is applied, with a 90-degree pulse 222 that rotates the spins into the transverse plane and a series of 180-degree pulses (two of which are indicated by 224) that generates a series of spin echoes (two of which are indicated by 226) whose amplitude depends on T₁ and whose decay depends on the transverse relaxation time constant, T₂

$$M ( {τ}_{1} , {τ}_{2} ) = {M}_{0} \int \int d {T}_{1} d {T}_{2} f ( {T}_{1} , {T}_{2} ) ( 1 - 2 {e}^{- \frac{{τ}_{1}}{{T}_{1}}} ) {e}^{- \frac{{τ}_{2}}{{T}_{3}}}$$

where T₁, T₂ and, τ₁ are as defined above, M₀ is the net magnetization of the spins at thermal equilibrium, τ₂ is the time from the start of the CPMG sequence, and f(T₁,T₂) is the two dimensional density function for T₁ and T₂. Other properties can be analyzed in a similar manner. For example, D-T₂ experiments can be performed to measure the diffusion properties of a data sample. As another example, high dimension data samples can also be analyzed in a similar manner.

Another example of a magnetic field pulse sequence that may be used in accordance with the invention includes a first part that is designed to prepare the system of spins in a driven equilibrium state. In general, any magnetic field pulse sequence that repeatedly rotates the net magnetization of the system between the longitudinal and the transverse directions will create a sizable driven equilibrium magnetization. As long as the repeating magnetic field pulse units are short compared to T₁ and T₂, it can be shown that the resulting equilibrium magnetization depends on a function of the ratio, T₁/T₂:

$${M}_{eq} = g ( \frac{{T}_{1}}{{T}_{2}} ) {M}_{0} .$$

After the spins are prepared in a driven equilibrium, a second part designed to refocus the spins of the system is applied. The second part generates a series of magnetic resonance signals that depends on both the T₁/T₂ ratio and T₂:

$${M}_{de} ( {τ}_{2} ) = {M}_{0} \int \int d {T}_{2} d \frac{{T}_{1}}{{T}_{2}} f ( {T}_{2} , \frac{{T}_{1}}{{T}_{2}} ) g ( \frac{{T}_{1}}{{T}_{2}} ) {e}^{- \frac{{τ}_{2}}{{T}_{2}}}$$

T₁, T₂, and τ₂ are as defined previously, and

$$f ( {T}_{2} , \frac{{T}_{1}}{{T}_{2}} )$$

is the two dimensional density function for the ratio T₁/T₂ and T₂.

FIG. 3 illustrates one example of such a driven equilibrium-refocusing sequence according to some embodiments of the invention. The magnetic field pulse sequence 300 includes a driven equilibrium Fourier transform (DEFT) sequence 310 followed by a CPMG sequence 320. The DEFT sequence 310 shown may be thought of as a repeating block 315 of magnetic field pulses generated according to:

[90₊ₓ−t₁−180_{y}−t₂−180_{y}−90₋ₓ]ᵢ,

where T₁ and T₂ (≈2T₁) are time differences between magnetic pulses. Each repeating block is separated by a time, δ₁, and each block has a total width of δ₂. FIG. 3 shows the sequence having two repeating blocks (i=2); however those of skill in the art will recognize that the sequence may have any number of repeating blocks. In many applications, it may be desirable to apply the DEPT sequence for a period of time longer than T₁. A magnetic resonance spin echo 317 appears midway between the two 180y-degree pulses of each block. Over time, the DEFT sequence prepares the system of spins in a driven equilibrium in which the magnetization, in the limit that δ₁<<T₁ and ε₂, is given as:

$${M}_{eq} \to \frac{{M}_{o}}{1 + \frac{{δ}_{2}}{{δ}_{1}} \frac{{T}_{1}}{{T}_{2}}} .$$

The asymptotic expression shown above offers a good approximation for the DEFT driven equilibrium magnetization for all parameters in the range of about T₂/δ₂≧10. After the system of spins is prepared in a driven equilibrium, a CPMG sequence 320 is applied, with a 90-degree pulse 322 followed by a series of 180-degree pulses (two of which are indicated by 324) to generate a series of magnetic resonance spin echoes (two of which are indicated by 326) whose signal is shown above, where the function

$$g ( \frac{{T}_{1}}{{T}_{2}} )$$

is given by:

$$g ( \frac{{T}_{1}}{{T}_{2}} ) = \frac{1}{1 + \frac{{δ}_{2}}{{δ}_{1}} \frac{{T}_{1}}{{T}_{2}}} ,$$

which is most sensitive to changes in T₁/T₂ in the region where (δ₁/δ₂)≈<T₁/T₂>.

In many cases the resulting NMR signal can be a superposition of many exponential decaying signals. The analysis of such data can be done using a Laplace inversion. The mathematic framework for such inversion can be described generally as M=KF, where M is a vector of measurement data, F is the discretized relaxation spectrum (or the model, in general), and K is the kernel matrix. The goal of the inversion is to obtain the relaxation spectrum F from the measured data M. The kernel function may be known for a specific experiment. For example, for T₂ relaxation, Kᵢⱼ=e^{-τ}^{ᵢ}^{/T}^{₂ⱼ}, where τ₁ is the decay time for the i^{th} data point and T₂ⱼ is the j^{th} component of T₂. A one-dimensional NMR experiment can produce a data vector of several thousands data points, and a two-dimensional or multi-dimensional experiments can produce up to 10⁶ data points. Correspondingly, the parameter matrix model F may have 100s of data points for one-dimensional experiments or around 10⁶ data points for multi-dimensional experiments. As a result, the kernel matrix can be extremely large.

Methods to solve this problem may involve several steps. First is the formulation of the problem and the kernel matrix. Second, several different algorithms can be used to reduce the matrix size for the data, model, and the kernel. The data, model, and kernel in this reduced space can be denoted M_{R}, F_{R}, and K_{R}, respectively. Third, an optimization is performed with the reduced kernel, data, and model to find a solution, F_{R}, so that the K_{R}F_{R} (matrix product of K_{R} and F_{R}) is consistent with M_{R}. The last step is to convert F_{R} back to F using the properties of the compression algorithm. There are many ways to compress the data. For example, this can be done using the window sum method, a singular value decomposition (SVD) method, or LU decomposition, where an LU decomposition—also called LU factorization—is a matrix decomposition where a matrix is written as the product of a lower triangular matrix and an upper triangular matrix. When the dataset is small, this step of data compression may be optional.

The window sum method basically bins the data and thus the kernel into a smaller data vector and a kernel matrix. This method is particularly effective for the inversion of CPMG type of multi-echo data where the time between the adjacent echoes is fixed, for example, to a range of hundreds of micro seconds and thousands of echoes are acquired. The method is usually performed by binning only the later echoes without losing sensitivity to the short time echoes. In a sense, this method is motivated by physics consideration and not by mathematics. For example, the choices of bins is primarily manual. The resulting binned data are not an orthogonal basis set.

SVD, on the other hand, is a general mathematical method for diagonalizing a matrix for data compression purposes. The benefit is the choice of basis set is automatic and the basis set is orthogonal, can handle any experiment and is not limited to CPMG. The choice of the number of the singular value can be done based on signal-to-noise ratio of the data. The downside is that it is relatively slow to compute and the entire kernel matrix and/or some copies of the kernel matrix may be stored in the memory. For example, the default Matlab SVDs routine requires four times the memory of the kernel matrix. Thus, this method (such as using Matlab svds) is very useful for one-dimensional NMR, however, it is not useful for two-dimensional or multi-dimensional NMR data analysis because of the extreme memory requirements. There are various different SVD algorithms including Jdsvd, Irlanb, Matlab SVDs, Irlbsvd, among others that can be used.

For certain NMR experiments resulting in a specific type of kernel matrix, the SVD method can be sped up by breaking the kernel into two submatrices. Calculation of each submatrix can be faster and can use much less memory. Once the two SVDs are done, both the singular values and singular vectors of the two matrices can be combined to reproduce the SVD of the original kernel. This method is extremely powerful, however, it only applies to certain classes of NMR experiments.

There can be four steps in performing Laplace inversion on NMR data. One of the steps can be data compression using, for example, SVD. The standard method of SVD cannot directly handle very large matrices due to memory and speed consideration. For example, for a two-dimensional NMR experiment using T₁ and T₂, a data matrix can have 30 values for τ₁ and 8,192 echoes for τ₂. The resulting data matrix will then have 30 times 8,192 data values or 245,760 data values. The model matrix can have 100 values for T₁ and 100 values for T₂; resulting in 10,000 values for the matrix model. The resulting kernel size would have 245,760 times 10,000 values or 2,457,600,000 values. If each value requires 8 bytes for a double data format, then this kernel would require around 20 GB. And because the standard SVD model requires about 4 times the memory as the kernel size, then this process would require about 80 GB of memory. Using window sum compression the kernel can be reduced to about 30,000,000 values, which is much more manageable than the process noted above.

In some embodiments, an efficient SVD algorithm (e.g., IRLBA or REF 5) can be used, which is significantly faster (e.g., around 10 times faster) than the routine SVD (e.g., Matlab svds) and also uses much less memory (e.g., about one fourth the memory of what Matlab svds uses). Accordingly, in some embodiments of the present invention, the augmented Implicitly Restarted Lanczos Bidiagonalization method (IRLBA) algorithm can be used as the second step for NMR Laplace inversion. This inversion algorithm can work a lot faster than using the standard SVD algorithms. And because the calculation of the SVD is done in one step, the result is generally more accurate than doing it in two separate matrices.

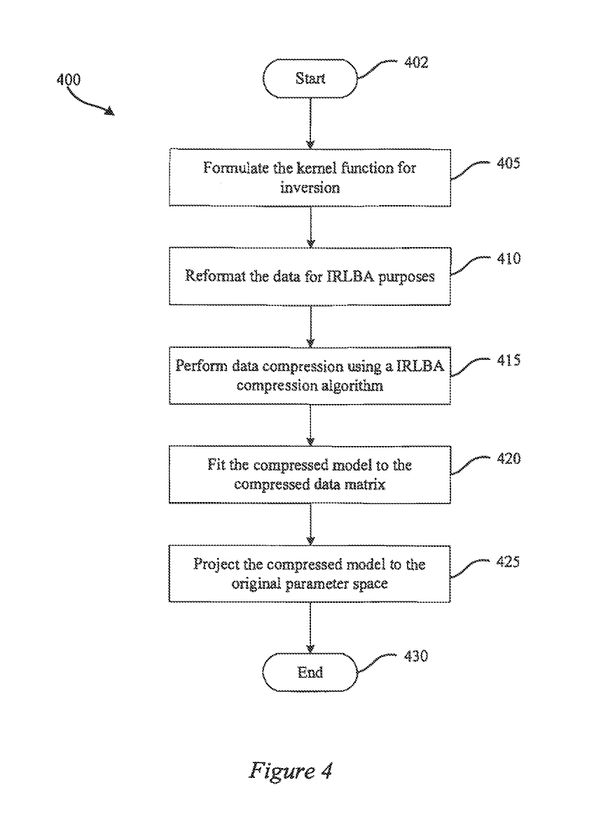

FIG. 4 is a flowchart of process 400 for performing a Laplace inversion using an IRLBA compression algorithm according to some embodiments of the present invention. Process 400, for example, can be computed on NMR data sets and/or on large data sets. Process 400 starts at block 402. At block 405 a kernel function can be formulated for the inversion. This can be done, for example, by choosing the kernel matrix, K, described above. Furthermore, inversion parameters, such as the grid precision to be used in evaluating F, the density distribution; type of kernel; type of optimization, noise, etc. can also be determined or chosen at block 405.

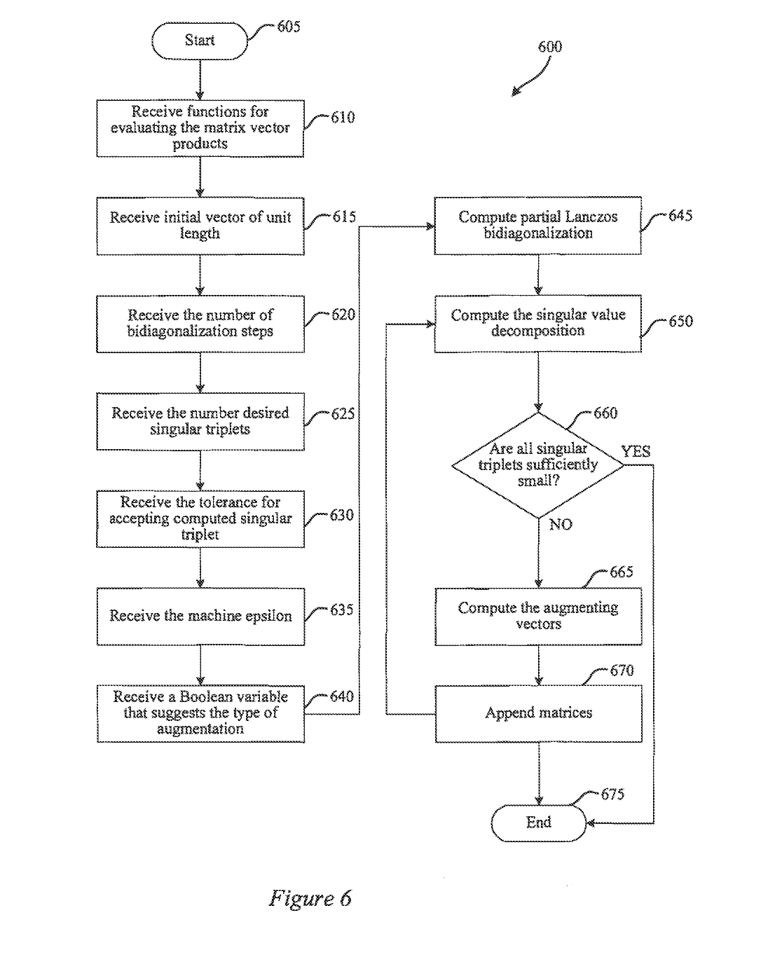

At block 410 the data set can be reformatted for IRLBA purposes. For example, two dimensional data can be held within a matrix. Yet some IRLBA functions can require the data to be presented as a matrix; such as, for example, IRLBA Matlab functions. Hence, at block 410, for example, columns of the data matrix can be combined end-to-end in a vector in order to be used in the IRLBA function. IRLBA compression can then be performed at block 415. The IRLBA compression algorithm can compute the partial Lanczos bidiagonalization for a partial SVD. Examples of a process for perfuming an IRLBA algorithm is shown in the flowchart of FIG. 6 and the related text.

At block 420 the compressed model can be fit with the compressed data. Referring to equation, M=KF, now that the data matrix, M, has been compressed, a kernel matrix, K, can be modified in order to determine F. At block 425, F can be computed from M=KF using the compressed data matrix and the modified kernel matrix. F can be used to return information about the region of interest, such as T₁, T₁/T₂, T₁-T₂ map, etc. At block 430 process 400 can end.

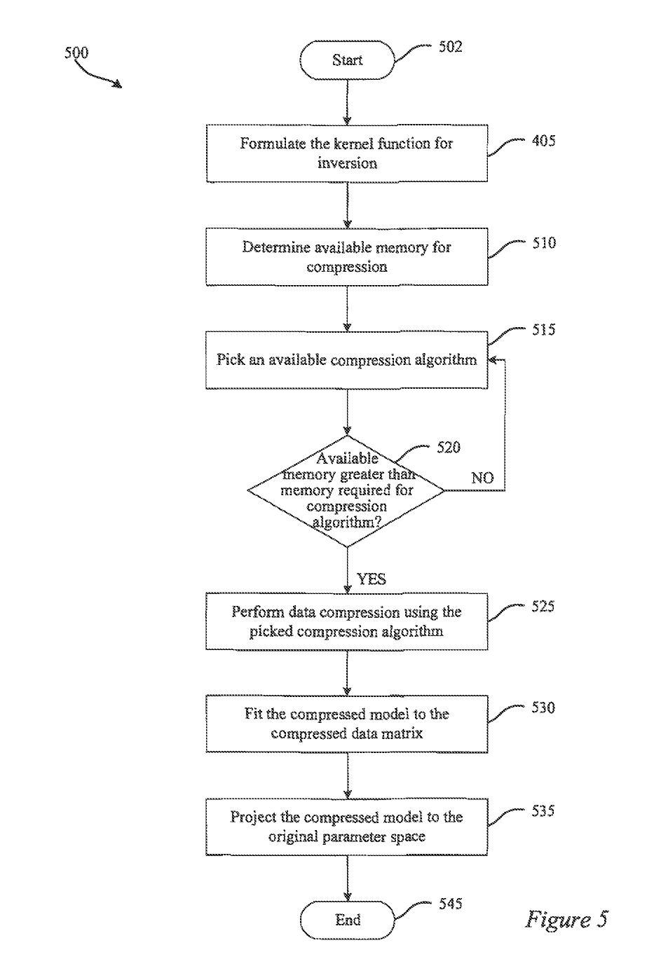

FIG. 5 is a flowchart of a process for choosing a compression algorithm during a Laplace inversion process according to some embodiments of the invention. Process 500 starts at block 502. At block 505, a kernel function, K, can be formulated for inversion. Block 505 can be similar to block 405 in FIG. 405 described above. At block 510 the processing memory available for running the compression algorithm can be determined. This can occur using any routine, technique, algorithm, applications, or processes that can determine the available memory of a computer system. For example, operating system 824 can determine how much working memory 820 is available for compression calculations. In some embodiments, an estimate of the available working memory can be used.

At block 515 a compression algorithm can be picked from a selection of compression algorithms. Compression algorithms can be picked in order of efficiency, in random order, or in order of precision. For example, a listing of compression algorithms can include Jdsvd, Matlab SVDs, Irlbsvd, IRLBA, or REF 5, to name a few, can be included. The amount of required memory can then be calculated for the first compression algorithm.

For example, for a two-dimensional NMR experiment using T₁ and T₂, a data matrix can have 30 values for τ₁ and 8,192 echoes for τ₂. The resulting data matrix will then have 30 times 8,192 data values or 245,760 data values. The model matrix can have 100 values for T₁ and 100 values for T₂; resulting in 10,000 values for the matrix model. The resulting kernel size would have 245,760 times 10,000 values or 2,457,600,000 values. If each value requires 8 bytes for a double data format, then this kernel would require around 20 GB. And because the standard SVD model requires about 4 times the memory as the kernel size, then this process would require about 80 GB of memory.

The amount of data required to calculate the compression algorithm can then be compared with the amount of available memory at block 520. If there is sufficient memory available then process 500 can proceed to block 525. In some embodiments, a buffer of operating memory can be subtracted from the amount of available memory that is then compared with the required memory for the picked compression algorithm. If the compression algorithm requires more memory than the available memory then process 500 returns to block 515 and another algorithm is selected from the listing of available compression algorithms. In the event that the memory requirements for every available compression algorithm has been compared with the available memory, then process 500 can end or the compression algorithm that requires the least amount of memory can be selected.

At block 525, the selected compression algorithm can compress the data. At block 530 the compressed model can be fit with the compressed data. Referring to equation, M=KF, now that the data matrix, M, has been compressed, a kernel matrix, K, must be modified in order to determine F. At block 535, F can be computed from M=KF using the compressed data matrix and the modified kernel matrix. F can be used to return information about the region of interest, such as T₁, T₁/T₂, T₁-T₂, D-T₂ map, etc. At block 545 process 500 can end.

In some embodiments, an IRLBA algorithm can utilize one or more Lanczos methods to transform and/or compress the data. In some embodiments, a restart Lanczos bidiagonalization method may be utilized where the algorithm restarts after a certain number of iterations. Some restart Lanczos methods may include augmenting a Krylov subspace. The augmented subspace may include Ritz and/or harmonic Ritz vectors, for example.

A Lanczos bidiagonalization method can be used to compute of some of the largest and smallest singular values of a large matrix. Lanczos methods generally involve a power method based iterative algorithm that can be used to determine the eigenvalues and eigenvectors of a square matrix or the singular value decomposition of a rectangular matrix. Power methods generally involve for each iteration, taking a vector, multiplying by the matrix, and then normalizing. The first vector can be a random vector, or approximation of the dominant eigenvector. The Lanczos method is well adapted for finding decompositions of very large sparse matrices.

An augmented Lanczos bidiagonalization method can also be used. In some embodiments, some methods can involve a thick restart. A thick restart involves restarting the algorithm after a certain number of iterations. The algorithm is also based on augmentation of a Krylov subspace with Ritz vectors or harmonic Ritz vectors. Krylov subspaces are subspaces that are generated by applying a matrix A (such as one of the matrices used in a Lanczos algorithm) repeatedly to a vector b and the resulting products (i.e. b, Ab, AAb, AAAb, . . . (A^{r})b).

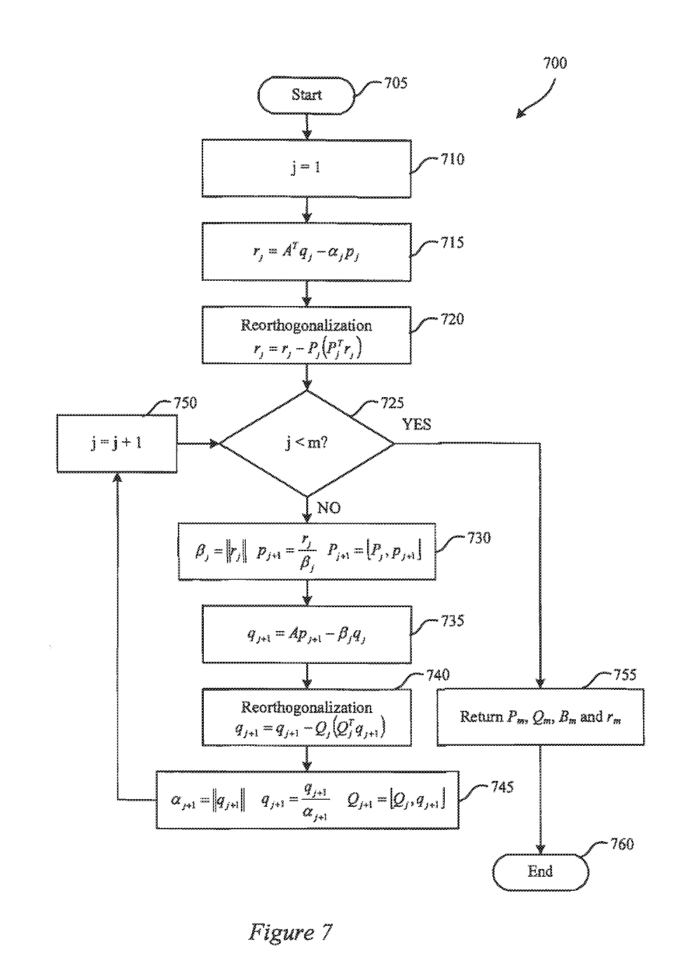

In some embodiments, an augmented Lanczos bidiagonalization method may be utilized as shown in the flowchart of process 600 in FIG. 6. Process 600, for example, can be executed using a computation system like the one shown in FIG. 7. Various other computer systems and processors may be utilized whether standard or special use. Process 600 begins at block 605. At blocks 610 through 640 various data and/or parameters are received. At block 610, functions for evaluating the matrix vector products are received. For example, these functions can be for evaluating matrix-vector products with the matrices A and A^{T}. This can be shown mathematically as Aε [symbol] ^{1×n}. The result of process 600 returns a complete set of approximate singular triplets {σⱼ, uⱼ,vⱼ}ⱼ₌₁^{k} of matrix A.

At block 615, the initial vector of unit length can be received. This can be represented mathematically as p₁ε [symbol] ⁿ. At block 620, the number of bidiagonalization steps, m, can be received. At block 625, the number of desired singular triplets can be received. The number of desired singular triplets, k, the tolerance for accepting computed approximate singular triplet, δ, and the machine epsilon, c, can be received at blocks 625, 630 and 635 respectively. At block 640 a Boolean value can be inputted that suggests the type of augmentation. Each of the data and/or parameters received through blocks 610-640 can be optional. For example, the machine epsilon can be standard for a certain machine and this value can be hard coded and not received. The same can be said fro the various other parameters.

At block 645 the partial Lanczos bidiagonalization can be computed. This can be done in any number of ways. For example, this can be done using the process shown in FIG. 7 and/or described below in conjunction with FIG. 7. As another example, the application of M steps of partial Lanczos bidiagonalization to the matrix A with initial unit vector p₁ε [symbol] ⁿ (received above in block 615) yields the decompositions

APₘ=QₘBₘ;A^{T}Qₘ=PₘBₘ^{T}+rₘeₘ^{T},

where Pₘe₁=p₁ and Pₘ^{T}rₘ=0. For small values of m, the singular triplets for Bₘ can be computed, for example, using the Golub-Kahan algorithm. And the singular triplets of A can be determined from the singular triplets of Bₘ and the matrices Pₘ and Qₘ.

At block 650 the singular value decomposition can be calculated. For example, the singular triplets of Bₘ can be calculated using:

Bₘvⱼ^{(B}^{ₘ}⁾=σⱼ^{(B}^{ₘ}⁾uⱼ^{(B}^{ₘ}⁾,Bₘ^{T}uⱼ^{(B}^{ₘ}⁾=σⱼ^{(B}^{ₘ}⁾vⱼ^{(B}^{ₘ}⁾,1≦j≦m.

At block 660, it can be determined if the singular triplets are sufficiently small. This can be determined, for example, if the convergence of all singular triplets satisfy βₘ|eₘ^{T}uⱼ^{(B}^{ₘ}⁾≦δ∥A∥, for a user specified value of δ. In some embodiments, ∥A∥ is approximated by the largest of the singular values of all matrices Bₘ generated. If the singular triplets are sufficiently small, then process 600 ends at block 675 and the singular triplets of Bₘ are used as the estimates for triplets of A. Otherwise process 600 proceeds to block 665.

At block 665 augmenting vectors can be computed. In some embodiments, this can be done in two different steps depending on whether Bₘ is harmonic and/or whether k(Bₘ) is greater than or less than ε^{-1/2}. In some embodiments, if Bₘ is not harmonic or k(Bₘ)>ε^{-1/2} then the following matrices can be determined P=\tilde{P}ₖ₊₁, Q=\tilde{Q}ₖ₊₁, and B=\tilde{B}ₖ₊₁, and the vector r=\tilde{f}ₖ₊₁ can be computed, where

$${\tilde{P}}_{k + 1} = [ {\tilde{u}}_{1}^{( A )} , {\tilde{u}}_{2}^{( A )} , … , {\tilde{u}}_{k}^{( A )} , {p}_{m + 1} ] , \\ {\tilde{Q}}_{k + 1} = [ {\tilde{u}}_{1}^{( A )} , {\tilde{u}}_{2}^{( A )} , … , {\tilde{u}}_{k}^{( A )} , \frac{{\tilde{r}}_{k}}{‖ {\tilde{r}}_{k} ‖} ] , \\ {\tilde{B}}_{k + !} = [ \begin{matrix}{\tilde{σ}}_{1}^{( A )} & & 0 & {\tilde{ρ}}_{1} \\ & ⋱ & & ⋮ \\ & & {\tilde{σ}}_{k}^{( A )} & {\tilde{ρ}}_{k} \\ 0 & … & & {\tilde{α}}_{k + 1}\end{matrix} ] , and$$

$${\tilde{f}}_{k + 1} = {A}^{T} \frac{{\tilde{r}}_{k}}{‖ {\tilde{r}}_{k} ‖} - {\tilde{γ}}_{1} {p}_{m + 1} .$$

And where \tilde{f}ₖ₊₁ε [symbol] ⁿ is orthogonal to the vectors ũⱼ^{(A)}, 1≦j≦k, as well as to pₘ₊₁.

In some embodiments, if Bₘ is harmonic or k(Bₘ)≦ε^{-1/2} then the singular value decomposition of B_{m,m+1} can be computed and matrices can be determined P=\hat{P}ₖ₊₁, Q=\hat{Q}ₖ₊₁, and B=\hat{B}ₖ₊₁, and the vector r=\check{r}ₖ₊₁. Where

$${\hat{P}}_{k + 1} = [ {\hat{p}}_{1} , {\hat{p}}_{2} , … , {\hat{p}}_{k + 1} ] := {P}_{m + 1} {Q}_{k + 1}^{′} , \\ {\hat{Q}}_{k} = {Q}_{m} {U}_{k}^{′} , \\ {\hat{B}}_{k + 1} = [ \begin{matrix}{σ}_{1}^{′} & & & 0 & {\hat{γ}}_{1} \\ & {σ}_{2}^{′} & & & {\hat{γ}}_{2} \\ & & ⋱ & & \\ & & & {σ}_{k}^{′} & {\hat{γ}}_{k} \\ 0 & & … & & {σ}_{k + 1}^{′}\end{matrix} ] , and$$

$${\breve{r}}_{k + 1} = {A}^{T} {\hat{q}}_{k + 1} - {\hat{α}}_{k + 1} {\hat{p}}_{k + 1} .$$

Once values for P, Q, B, and r are determined, regardless of the way in which they were determined, the matrices can be appended at block 670. For example, columns M-K can be appended to the P and Q matrices and rows and columns M-K can be appended to the matrix B. These matrices can then be denoted Pₘ, Qₘ, and Bₘ respectively. A new residual vector can be determined and denoted rₘ. The process 600 can return to block 650 and portions of process 600 can be repeated with these new values until the singularities are determined to be sufficiently small at block 660.

FIG. 7 shows an example of process 700 for completing a partial Lanczos bidiagonalization of a matrix denoted A. Process 700 begins at block 705. In some embodiments, the matrix, A can be inputted or read from memory prior to starting. An initial vector of unit length, p₁ can also be inputted as well as the number of diagonalization steps, m. Prior to computing the diagonalization steps, a few definitions may be used/provided P₁=p₁, q₁=Ap₁, α₁=∥q₁∥,

$${q}_{1} = \frac{{q}_{1}}{{α}_{1}} ,$$

and Q₁=q₁. At block 710 counter j can be initialized. At block 715 the residual vector can be determined for j=1 using rⱼ=A^{T}qⱼ−αⱼpⱼ.

At block 720, reorthogonalization of the residual vector can occur using, for example, r₁=r₁−P₁(P₁^{T}r₁). At block 725, if j is less than the number of bidiagonalization steps, m, then process 700 can proceed to block 730. Other wise process 700 can proceed to block 755. At block 730 a few parameters can be set: βⱼ=∥rⱼ∥;

$${p}_{j + 1} = \frac{{r}_{j}}{{β}_{j}} ;$$

Pⱼ₊₁=└Pⱼ, pⱼ₊₁┘. And at block 735 qⱼ₊₁=Apⱼ₊₁−βⱼqⱼ Reorthogonalization can the occur at block 740 on the j^{th} term using qⱼ₊₁=qⱼ₊₁−Qⱼ(Qⱼ^{T}qⱼ₊₁). Then at block 745 the parameters can be reset using αⱼ₊₁=∥qⱼ₊₁∥;

$${q}_{j + 1} = \frac{{q}_{j + 1}}{{α}_{j + 1}} ,$$

and Qⱼ₊₁=└Qⱼ,qⱼ₊₁┘. Following block 745 the counter, j, can be incremented at block 750 and process 700 can return to block 725.

If the number of bidiagonalization steps has been reached at block 725, then process 700 proceeds to block 755 where Pₘ, Qₘ, Bₘ, and rₘ can be returned. Where Pₘ=[p₁, p₂, . . . , pₘ] and Qₘ=[q₁, q₂, . . . , qₘ], both of which are matrices with orthonormal columns. And Bₘε [symbol] ^{m×m} is an upper bidirectional matrix with entries αⱼ and βⱼ.

The various embodiments described herein can be performed on conventional NMR systems. These systems can include high field NMR and low field NMR systems. These systems can have highly uniform magnetic fields. For example, NMR studies on milk and cheeses can be performed at low magnetic fields with constant field gradients. Thus, while typical methods can require highly uniform high magnetic fields, some embodiments described herein can be used with low magnetic fields and/or with constant field gradients. For instance, a magnetic field of 400 G can be easily achieved using a permanent magnet with a cost far below that of a superconducting magnet. Furthermore, because a constant field gradient can be compatible with some of the embodiments, simple magnet designs can be employed compared to the complex designs required for the uniformed fields, e.g. a Halbach design. This simplicity coupled with the flexibility and the lower cost makes it possible to fit such a magnet into existing production lines, for example, a pipeline or a conveyer belt.

The time required for the two-dimensional experiment is another important consideration for the feasibility of such technique. Since it is a two-dimensional method, the total experimental time is often detei mined by the number (N₁) of values along the first dimension, e.g. τ₁ in a T₁-T₂ experiment. The required N₁ is constraint to the range of the parameter, signal-to-noise ratio, and the desired resolution in the spectrum. For example, one of the first two-dimensional NMR logging experiments used 9 values of t_{cp1} and was executed in about 10 min. With a higher magnetic field and a better filling-factor coil, the need for signal averaging can be reduced and the experimental time further minimized. It is possible to perform such two-dimensional experiment in 10-20 seconds.

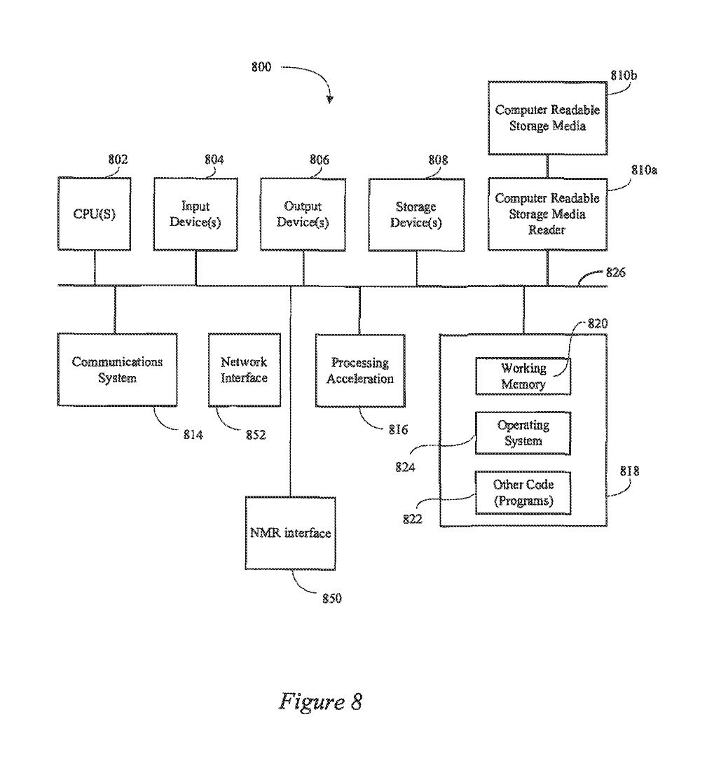

Moreover, FIG. 8 is a simplified block diagram of computer system 800 that can be used to perform various embodiments of the invention. In some embodiments, the computer system 800 can be coupled directly with an NMR device through NMR interface 850. Data can be input directly from the NMR device and stored or processes by computer system 800. In some embodiments, NMR data can be inputted using input device 204. For example, a data collection device can be used during the recording process and the NMR data can be stored thereon. The NMR data can then be transferred to computer system 800 from data collection device.

Computer system 800 can be used to perform any or all the steps shown in FIGS. 4-8. Moreover, computer system 800 can perform any or all the mathematical computations disclosed here. The drawing illustrates how individual system elements can be implemented in a separated or more integrated manner. Computer system 200 is shown having hardware elements that are electrically coupled via bus 826. Network interface 852 can communicatively couple the computational device 800 with another computer, for example, through a network such as the Internet. The hardware elements can include a processor 802, an input device 804, an output device 806, a storage device(s) 808 (e.g., hard disk drive), a computer-readable storage media reader 810a, a communications system 814, a processing acceleration unit 816 such as a DSP or special-purpose processor, and memory 818 (e.g., random access memory (RAM)). The computer-readable storage media reader 810a can be further connected to a computer-readable storage medium 810b, the combination comprehensively representing remote, local, fixed, and/or removable storage devices plus storage media for temporarily and/or more permanently containing computer-readable information.

NMR interface 850 can be coupled with bus 826. In some embodiments, NMR interface 850 can be any type of communication interface. For example, NMR interface 850 can be a USB interface, UART interface, serial interface, parallel interface, etc. NMR interface 850 can be configured to couple directly with any type of nuclear magnetic resonance system. Such as, for example, high field NMR systems and low field NMR systems.

The computer system 800 also comprises software elements, shown as being currently located within working memory 820, including an operating system 824 and other code 822, such as a program designed to implement methods and/or processes described herein. In some embodiments, other code 822 can include software that provides instructions for compressing and/or analyzing NMR data, or instructions for extracting information and manipulating the NMR data according to various embodiments disclosed herein. In some embodiments, other code 822 can include software that can predict or forecast weather events, and/or provide real time weather reporting and/or warnings. It will be apparent to those skilled in the art that substantial variations can be used in accordance with specific requirements. For example, customized hardware might also be used and/or particular elements might be implemented in hardware, software (including portable software, such as applets), or both. Further, connection to other computing devices such as network input/output devices can be employed. Moreover, working memory 820 may also be used by computer system 800 during processing. For example, computational parameters, vectors, and/or matrices can be stored in working memory 820 during any of the computation disclosed herein or others references herein.

Embodiments described herein can be used, for example, in studying rock formations, oil well-logging, food product process control, pharmaceutical production and testing and/or the like. For instance, sedimentary rocks from oil reservoirs exhibit significant porosity where crude oils and water coexist in the same pore space. The characterization of the pore structure and the fluids in situ is essential in the development of oilfields and specifically in the design of production strategy and facility. NMR tools can be lowered into a well and NMR data can be logged at various well depths. With a potentially large data set embodiments described herein can be used to compress the data prior to analyzing the data. Information such as pore size, fluid viscosity, and/or saturation, among others, can be determined from the data.

Food products can be considered generally as a mixture of many components. For example, milk, cream and cheeses are primarily a mixture of water, fat globules and macromolecules. The concentrations of the components are important parameters in the food industry for the control of production processes, quality assurance, and the development of new products. NMR has been used extensively to quantify the amount of each component, and also their states. For example, lipid crystallization has been studied in model systems and in actual food systems. Callaghan et al. have shown that the fat in Cheddar cheese was diffusion-restricted and was most probably associated with small droplets. Embodiments described here can be used in applications of NMR and MRI in food science and processing. In many products, the spin relaxation properties of the components can be different due to molecular sizes, local viscosity, and interaction with other molecules. These parameters can be determined using, in part, embodiments described herein.

Embodiments of the invention can be applied to many other materials. Even though this technique is mostly sensitive to the mobile species of protons, we have found a strong signal in many solid samples, such as hard candies, chocolates, and pills, to name a few.

Some embodiments described herein provide for methods that choose an SVD algorithm based on the available processing memory. Plots of data produced using an SVD algorithm have been compared with and have been found to be consistent with data plots obtained using the augmented Lanczos bidiagonalization algorithm described above (the plot on the right). Similarly, inversion results (T₁-T₂ spectrum) from the two algorithms are essentially the same. Furthermore, one dimensional projections of the results from the two algorithms, reviewed by overlaying the results for T₁ and T₂ projections obtained from the two algorithms, are essentially identical.

While the principles of the disclosure have been described above in connection with specific apparatuses and methods, it is to be clearly understood that this description is made only by way of example and not as limitation on the scope of the invention.

What is claimed is:

1. A nuclear magnetic resonance processing system for analyzing physical properties of a material, comprising:
a nuclear magnetic resonance interface configured to receive two or three dimensional nuclear magnetic resonance data from a nuclear magnetic resonance system that is configured to obtain nuclear magnetic measurements from the material;
a processing unit coupled with the nuclear magnetic resonance interface, the processing unit configured to:
receive the nuclear magnetic resonance data from the nuclear magnetic resonance interface,
express the nuclear magnetic resonance data using a kernel,
compress the nuclear magnetic resonance data using a Lanczos bidiagonalization algorithm, and
evaluate a physical property of the material using the compressed nuclear magnetic resonance data.

2. The nuclear magnetic resonance processing system according to claim 1, further comprising a display configured to display the physical property of the material.

3. The nuclear magnetic resonance processing system according to claim 1, wherein the processing unit is further configured to transform the nuclear magnetic resonance data into a vector prior to compressing the nuclear magnetic resonance data.

4. The nuclear magnetic resonance processing system according to claim 1, wherein the nuclear magnetic resonance data, a model matrix of the nuclear magnetic resonance data, and/or the kernel are not reduced in size prior to compression by the Lanczos bidiagonalization algorithm.

5. The nuclear magnetic resonance processing system according to claim 1, wherein the Lanczos bidiagonalization algorithm is used to compress all of a two or three dimensional nuclear magnetic resonance data.

6. The nuclear magnetic resonance processing system according to claim 1, wherein the Lanczos bidiagonalization algorithm is used to compress two or three dimensional nuclear magnetic resonance data in a single step.

7. The nuclear magnetic resonance processing system according to claim 1, wherein the Lanczos bidiagonalization algorithm is an augmented Implicitly Restarted Lanczos Bidiagonalization method (IRLBA) algorithm.

8. A nuclear magnetic resonance processing system comprising:
a nuclear magnetic resonance interface configured to receive nuclear magnetic resonance data from a nuclear magnetic resonance system;
operating memory with a finite size; and
a processing unit coupled with the operating memory and the nuclear magnetic resonance interface, the processing unit configured to:
determine the kernel of the magnetic resonance data using a kernel function;
determine the available operating memory, wherein the available operating memory is the amount of memory available in the operating memory and
compress the kernel of the nuclear magnetic resonance data using a compression algorithm that does not require any more memory than the available operating memory.

9. The nuclear magnetic resonance processing system according to claim 8, wherein the processing unit is further configured to analyze the compressed nuclear magnetic resonance data to extract information about the system of nuclear spins.

10. The nuclear magnetic resonance processing system according to claim 8 wherein the compression algorithm comprises an IRLBA algorithm.

11. The nuclear magnetic resonance processing system according to claim 8 wherein the compression algorithm comprises a window sum algorithm.

12. The nuclear magnetic resonance processing system according to claim 8, wherein the compression algorithm comprises any Lanczos bidiagonalization algorithm.

13. The nuclear magnetic resonance processing system according to claim 8, wherein the processing unit is further configured to transform the nuclear magnetic resonance data into a vector prior to compressing the nuclear magnetic resonance data.

14. A method of extracting information about a system of nuclear spins, the method operable by a computer system comprising random access memory (RAM), the method comprising:
performing a plurality of nuclear magnetic resonance measurements on the system of nuclear spins;
acquiring nuclear magnetic resonance data from the plurality of nuclear magnetic resonance measurements;
expressing the nuclear magnetic resonance data using a kernel;
determining the available memory in the computer system's RAM;
selecting a compression algorithm that does not require any more memory than the available RAM;
compressing the nuclear magnetic resonance data using the selected compression algorithm; and
analyzing the compressed nuclear magnetic resonance data to extract information about the system of nuclear spins.

15. The method according to claim 14, wherein the selected compression algorithm comprises a IRLBA compression algorithm.

16. The method according to claim 14, wherein the selected compression algorithm comprises a Lanczos bidiagonalization algorithm.

17. The method according to claim 14, wherein the nuclear magnetic resonance data is compressed along each dimension of the kernel.

18. The method according to claim 14, wherein the selecting a compression algorithm that does not require any more memory than the available RAM includes selecting the compression algorithm from a listing of compression algorithms that require a variety of memory for processing.

19. The method according to claim 18, wherein the listing of compression algorithms includes two or more algorithms selected from the group consisting of Jdsvd, IRLBA, Matlab SVDs, and Irlbsvd.

20. The method according to claim 18, wherein the listing of compression algorithms includes two or more single value decomposition algorithms.

21. A method of extracting information about a system of nuclear spins comprising:
performing a plurality of nuclear magnetic resonance measurements on the system of nuclear spins;
acquiring nuclear magnetic resonance data from each of the plurality of nuclear magnetic resonance measurements;
expressing the nuclear magnetic resonance data using a kernel;
compressing the nuclear magnetic resonance data using a Lanczos bidiagonalization algorithm; and
analyzing the compressed nuclear magnetic resonance data to extract information about the system of nuclear spins.

22. The method according to claim 21, wherein the Lanczos bidiagonalization algorithm comprises an IRLBA algorithm.

23. A method comprising:
acquiring data about a measurement system;
expressing the data using a kernel resulting in kernel data;
compressing the kernel data using a Lanczos bidiagonalization algorithm that returns compressed data; and
analyzing the compressed data to extract information about the measurement system.

24. A method comprising:
acquiring data about a measurement system;
determining the available operating memory;
expressing the data using a kernel resulting in kernel data;
compressing the kernel data using a compression algorithm that does not require any more memory than the available operating memory; and
analyzing the compressed data to extract information about the measurement system.

25. The method according to claim 24, wherein the compression algorithm is selected from the list comprising an IRLBA algorithm and any Lanczos bidiagonalization algorithm.
